(19) United States
(12) Patent Application Publication
(10) Pub. No.: US 2004/0040663 A1
(43) Pub. Date: Mar. 4, 2004

(54) Plasma processing apparatus

(76) Inventors: Ryujiro Udo, Ushiku (JP); Masatsugu Arai, Niihari-gun (JP); Masanori Kadotani, Kudamatsu (JP)

Correspondence Address: ANTONELLI, TERRY, STOUT & KRAUS, LLP, 1300 NORTH SEVENTEENTH STREET, SUITE 1800, ARLINGTON, VA, 22209-9889, US

(21) Appl. No.: 10/230,299

(22) Filed: Aug. 29, 2002

(51) Int. Cl. H01L 21/306

(52) U.S. Cl. 156/345.51

(57) ABSTRACT

The plasma processing apparatus includes a process chamber for processing a sample, evacuation means for decompressing the process chamber, process gas supply means for supplying a process gas to the process chamber, sample holder means for holding the sample processed in the process chamber, bias applying means for applying a bias potential to the sample holder means, electrostatic chucking means for holding the sample to the sample holder means with electrostatic action, and plasma generator means for generating a plasma in the process chamber, in which the sample holder means has a step on an upper surface thereof, the sample is mounted on the uppermost step, a ring member made of a conductive material to which the bias potential can be applied is provided on a surface lower than the surface on which the sample is mounted, the upper surface of the ring member is at the same level as or below the upper surface of the sample, and the upper surface of the ring member is covered with a member made of a dielectric material.

### BACKGROUND OF THE INVENTION

1. Field of the Invention

The present invention relates to a plasma processing apparatus. In particular, it relates to a plasma processing apparatus that processes a sample, such as a wafer, in uniform manner within the wafer plane.

2. Description of the Related Art

As a semiconductor manufacturing apparatus for manufacturing a semiconductor device by processing a plate material, such as a silicon wafer (hereinafter referred to as a wafer), a plasma processing apparatus, such as a plasma CVD (chemical vapor deposition) apparatus and a plasma etching apparatus is being widely used. For such plasma processing apparatus, it is generally essential that the wafer is processed uniformly in a plane thereof. For example, in the plasma CVD apparatus, the film deposition rate and the film composition are required to be as uniform as possible in the plane of the wafer. In the plasma etching apparatus, the etching rate and the shape of trenches or holes are required to be as uniform as possible in the plane of the wafer. If a sufficient uniformity is not attained, semiconductor devices formed on the same wafer may vary in performance or a failed device may result. Further, the manufacturing yield thereof may be reduced, resulting in an increase of the cost of the semiconductor device.

In particular, the non-uniformity of the wafer processing caused by mechanical, electromagnetic or thermal specificity or the like near the peripheral edge of the wafer may make it impossible to fabricate a semiconductor chip using the peripheral edge of the wafer. In this case, the process is designed to have no chip fabricated in the peripheral region of the wafer where chips cannot be produced. Such a region near the peripheral edge of the wafer which is not used under the design rule is referred to as an edge exclusion (hereinafter abbreviated as E.E.), which is one of the factors that determine the price of the semiconductor chip.

Conventionally, various ways to improve the uniformity in the plane of the processing wafer in the plasma processing apparatus has been considered. For example, Japanese Patent Laid-Open Publication No. 7-66174 discloses a technique of eliminating or substantially reducing electric lines of force that are not perpendicular to the wafer by providing a “ring” made of an insulating or dielectric material and having a “wall” selected to provide uniform plasma sheath throughout the whole surface of the wafer, the ring being used with a pedestal for supporting the wafer.

However, the plasma processing apparatus described in the Japanese Patent Laid-Open Publication No. 7-66174 is a batch type etching apparatus, and this invention is suitable for an apparatus in which the wafer is mechanically clamped in a slanting position with a holding clip to a wafer stage referred to as a pedestal. It has been proved that various difficulties arise when this invention is to be applied to an apparatus that has become popular in recent years, that is, an apparatus in which wafers are delivered one after another by automatic delivery means to be mounted horizontally on sample holder means and held thereto by electrostatic chucking, and having a bias potential applied to the sample holder means.

Other than the disclosure of Japanese Patent Laid-Open Publication No. 7-66174, the technique of providing a conductor or dielectric ring around the sample holder means to affect an electric field on the wafer is known from Japanese Patent Laid-Open Publication Nos. 11-74099 and 2001-185542. Objects and problems to be solved by the invention disclosed in these specifications vary. However, with the configurations described in the specifications, the electric lines of force caused by the bias potential that are not perpendicular to the wafer surface could not be eliminated or reduced substantially.

Thus, in view of such problems, the object of the present invention is to provide a plasma processing apparatus capable of processing a wafer uniformly in a plane thereof by providing a uniform electric field intensity throughout the peripheral edge of the wafer, in other words, capable of keeping electric lines of force substantially perpendicular to the wafer surface when a bias potential is applied to the wafer, thereby preventing or relieving concentration of the electric field on the peripheral edge of the wafer.

### SUMMARY OF THE INVENTION

In order to solve the problems described above, the present invention includes the following means.

That is, the plasma processing apparatus according to the present invention comprises a process chamber for processing a sample, evacuation means for decompressing the process chamber, process gas supply means for supplying a process gas to the process chamber, sample holder means for holding the sample processed in the process chamber, bias applying means for applying a bias potential to the sample holder means, electrostatic chucking means for holding the sample to the sample holder means with electrostatic action, and plasma generator means for generating a plasma in the process chamber, in which the sample holder means has a step on an upper surface thereof, the sample is mounted on the uppermost step, a ring member made of a conductive material to which the bias potential can be applied is provided on a surface lower than the surface on which the sample is mounted, the upper surface of the ring member is at the same level as or below the upper surface of the sample, and the upper surface of the ring member is covered with a member made of a dielectric material.

### BRIEF DESCRIPTION OF THE DRAWINGS

FIG. 1 is a schematic cross-sectional view of a plasma etching apparatus to which the present invention is applied;

FIG. 2 is an enlarged view of a periphery of a wafer W in FIG. 1;

FIG. 3 shows a result of analysis of an electric field distribution provided by a bias potential in the arrangement of FIG. 2;

FIG. 4 is an enlarged view of the periphery of the wafer W according to the prior art example;

FIG. 5 shows a result of analysis of the electric field distribution provided by the bias potential in the arrangement of FIG. 4;

FIG. 6 is a graph showing the relation between a distance from the center of the wafer and an angle θ between the electric line of force and the wafer surface;

FIG. 7 is a graph showing the relation between a distance from the center of the wafer and an electric field intensity E;

FIG. 8 is an enlarged view of the periphery of the wafer W in the plasma etching apparatus to which another embodiment of the present invention is applied;

FIG. 9 shows a result of analysis of the electric field distribution provided by the bias potential in the arrangement of FIG. 8;

FIG. 10 is a graph showing the relation between the distance from the center of the wafer and an angle θ between the electric line of force and the wafer surface;

FIG. 11 is a graph showing the relation between the distance from the center of the wafer and the electric field intensity;

FIG. 12 is an enlarged view of the periphery of the wafer W in the plasma etching apparatus to which another embodiment of the present invention is applied;

FIG. 13 is an enlarged view of the periphery of the wafer W in the plasma etching apparatus to which another embodiment of the present invention is applied; and

FIG. 14 is a graph showing the relation among difference Hw−Hf, difference Df−Dw and the angle θ between an electric line of force and a wafer surface.

### DETAILED DESCRIPTION OF THE PREFERRED EMBODIMENTS

Now, a first embodiment of the present invention will be described in detail with reference to the drawings.

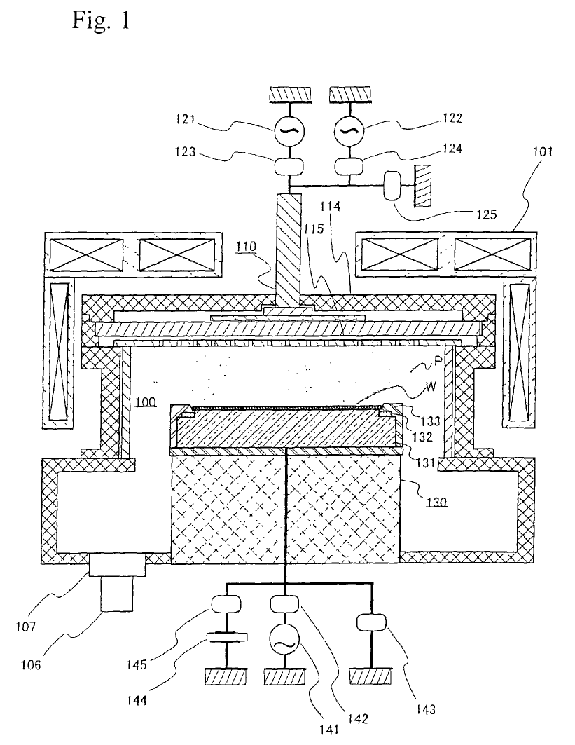

FIG. 1 is a schematic cross-sectional view of a plasma etching apparatus, illustrating an example of the present invention applied to the plasma etching apparatus.

In FIG. 1, a process chamber 100 is a vacuum container capable of attaining a pressure on the order of 10⁻⁴ Pa. An antenna 110 for radiating an electromagnetic wave is provided at an upper portion of the process chamber, and a lower electrode 130 on which a sample W, such as a wafer, is to be mounted is provided at a lower portion thereof. The antenna 110 and the lower electrode 130 are disposed in parallel facing each other. Magnetic field generator means 101, which is composed for example of an electromagnetic coil and a yoke is disposed around the process chamber 100. The electromagnetic wave radiated from the antenna 110 and the magnetic field generated by the magnetic field generator means 101 interact with each other to change the process gas introduced into the process chamber into a plasma P, with which the sample W is processed.

The process chamber 100 is evacuated by evacuation means 106 and the pressure thereof is controlled by pressure control means 107. A process pressure is controlled to fall within the range from 0.1 Pa to 10 Pa inclusive. The process chamber 100 is maintained at a ground potential.

The antenna 110 is held in a housing 114 which constitutes apart of the vacuum container. A shower plate 115 is disposed on a surface of the antenna 110 which is in contact with the plasma. The process gas for processing the sample, such as etching and film deposition, is supplied from gas supply means (not shown) with predetermined flow rate and mixture ratio, controlled to have a predetermined distribution via a large number of holes provided in the shower plate 115, and supplied to the process chamber 100.

An antenna power supply 121 and an antenna bias power supply 122 are connected to the antenna 110 via matching circuit and filter systems 123 and 124, respectively. The antenna 110 is grounded via a filter 125. The antenna power supply 121 supplies a power on an UHF frequency band from 300 MHz to 1 GHz. In this embodiment, the frequency of the antenna power supply 121 is 450 MHz. On the other hand, the antenna bias power supply 122 applies to the antenna 110 a bias power on a frequency from several tens kHz to several tens MHz. In this embodiment, the frequency thereof is 13.56 MHz. The sample W is a wafer having a diameter of 300 mm.

A bias power supply 141 that supplies a bias power on a frequency from 200 kHz to 13.56 MHz, for example, is connected to the lower electrode 130 via a matching circuit and filter system 142 to control the bias applied to the sample W, and the lower electrode 130 is grounded via a filter 143. In this embodiment, the frequency of the bias power supply 141 is 400 kHz.

The lower electrode 130 has a wafer stage 131, and the sample W, such as a wafer, is mounted on an upper surface of the wafer stage functioning as a sample mounting surface. The wafer stage 131 comprises a base material of aluminum and a dielectric layer for electrostatic chucking (hereinafter referred to as a dielectric film) formed on an upper surface of the base material. A direct current voltage of several hundreds V to several kV is applied to the wafer stage 131 by a direct current power supply 144 for electrostatic chucking through a filter 145 to produce an electrostatic force, thereby sucking and holding the sample W, such as a wafer. For the dielectric film, a dielectric material such as alumina or alumina mixed with titania is used. The temperature of the surface of the wafer stage 131 is controlled to a predetermined value by temperature control means (not shown) . An inert gas, such as He gas, is supplied to the surface of the wafer stage 131 with predetermined flow rate and pressure to enhance the thermal conductivity between the surface and the sample W. In this way, the surface temperature of the sample W can be precisely controlled to fall within a range from 20° C. to 110° C., for example. The diameter of the upper surface of the wafer stage 131 is smaller than the diameter of the sample W by 1 to 2 mm. This prevents the dielectric film on the upper surface of the wafer stage 131 from being directly exposed to the plasma, that is, from being damaged by the plasma, thereby ensuring a long use thereof.

The wafer stage 131 has a step on the upper surface thereof. The sample W is mounted on the uppermost step, and a conductor ring 132, which is a ring member made of a conductive material to which a bias potential is applied, is provided on a surface lower than the sample mounting surface. The upper surface of the ring member is preferably at the same level as or below the upper surface of the sample.

The conductor ring 132 is made of aluminum. This is because it is essential that the surface of the conductor ring 132 is at the same potential as the wafer stage 131 when the bias is applied thereto, and this requires the conductor ring 132 to have the same electrical characteristics as the wafer stage 131. Besides, if the temperatures of the wafer stage 131 and the conductor ring 132 change, these members thermally expand or shrink. If these members are made of different materials and have different coefficients of thermal expansion, a thermal stress may be generated between the wafer stage 131 and the conductor ring 132, resulting in an irregular deformation thereof. If the conductor ring 132 is irregularly deformed, the electric field distribution may change at the periphery of the wafer. Therefore, the conductor ring 132 is preferably made of a material having a coefficient of thermal expansion substantially the same as that of the wafer stage 131.

If necessary, the surface of the conductor ring 132 is coated with a dielectric film formed by anodization (so-called alumite) or surface processing such as thermal spraying (thermal-sprayed film), thereby preventing abnormal discharge or short-circuit.

The upper surface of the conductor ring 132 is covered with a cover ring 133 made of a dielectric material or the like to prevent the conductor ring from being reduced in thickness by exposure to the plasma. The cover ring 133 is suitably made of a ceramic such as alumina, or quartz. In this embodiment, the cover ring 133 is made of alumina prepared by sintering.

The height of the cover ring 133 must be carefully considered. The uppermost surface of the cover ring 133 is preferably at the same level as or higher than the upper surface of the wafer W. In addition, the difference between the heights thereof is preferably equal to or less than 2 mm. This is because if the uppermost surface of the cover ring 133 is lower than the upper surface of the wafer W, the electric field may be undesirably concentrated on the periphery of the upper surface of the wafer W. However, if the uppermost surface of the cover ring 133 is higher than the upper surface of the wafer W by more than 2 mm, the contaminant deposited on the cover ring 133 may undesirably fall on the wafer W.

Now, the effect of a uniform electric field distribution on the wafer provided by the apparatus according to this embodiment will be described in detail.

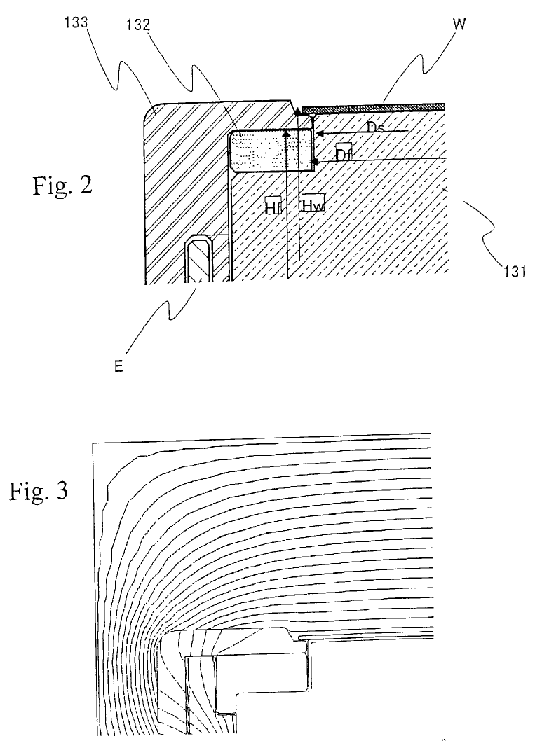

FIG. 2 is an enlarged view of a periphery of the wafer W in FIG. 1. In FIG. 2, a difference Hw−Hf between a height Hw to the upper surface of the wafer W and a height Hf to the upper surface of the conductor ring 132 is 2.6 mm, and a difference Df−Ds between an inner diameter Df of the conductor ring and an outer diameter Ds of the uppermost step of the wafer stage 131 is 0.3 mm. The surface of the conductor ring 132 is anodized. This is intended to prevent the inner periphery of the conductor ring 132 from being in contact with the plasma and etched thereby. Furthermore, while in FIG. 2, a grounding terminal E is provided in the cover ring 133, the position of the grounding terminal E is not necessarily limited to the inside of the cover ring, and it can also be positioned outside the cover ring. In addition, the bias to the lower electrode 130 in FIG. 2 is applied to the wafer stage 131 and the conductor ring 132 by regarding them as one conductor unit.

FIG. 3 shows a result of analysis of an electric field distribution provided by the bias potential at this time. As can be seen from FIG. 3, equipotential surfaces provided by the bias potential are substantially parallel with the upper surface of the wafer W from the vicinity of the center thereof to the peripheral edge thereof.

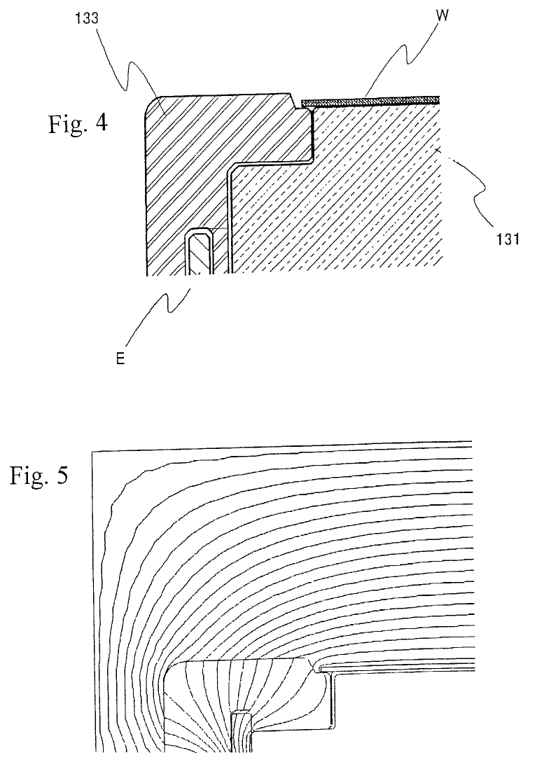

On the other hand, FIG. 4 shows a prior art example illustrating an enlarged view of a periphery of the wafer W where the conductor ring is not used. Furthermore, FIG. 5 shows a result of analysis of an electric field distribution provided by the bias potential in the arrangement shown in FIG. 4. As can be seen from FIG. 5, a distance between equipotential surfaces provided by the bias potential becomes narrower in the vicinity of the peripheral edge of the wafer W, which indicates that the electric field is concentrated and becomes more intense in that area.

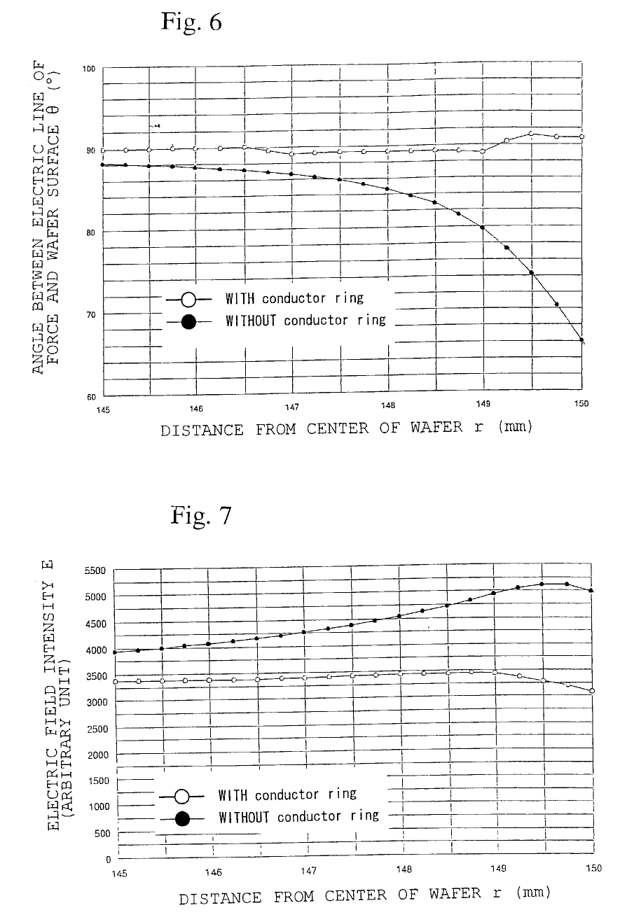

Such non-uniformity of the electric field distribution is more apparently seen from graphs of FIGS. 6 and 7. FIG. 6 is a graph showing the result of analysis of the relation between the distance r from the center of the wafer W and an angle θ between the electric line of force 1 mm above the wafer and the wafer surface. It will be understood that if the conductor ring 132 is used, the electric line of force is substantially perpendicular to the wafer surface. On the other hand, if the conductor ring is not used, the angle between the electric line of force and the wafer surface becomes smaller in the region closer to the wafer peripheral edge (150 mm), and is about 66° near the wafer peripheral edge.

FIG. 7 is a graph showing the result of analysis of the relation between a distance from the center of the wafer W and an electric field intensity E at a position 1 mm above the wafer. It will be understood that if the conductor ring 132 is used, the electric field intensity E is substantially uniform throughout the wafer reaching the outermost edge of the wafer. On the other hand, if the conductor ring is not used, it is apparent that the electric field intensity E becomes higher in the region closer to the wafer peripheral edge (150 mm). Thus, according to the present invention, the angle between the electric line of force provided by the bias potential and the wafer surface can be at substantially right angle even at the wafer peripheral edge, and therefore, charged particles in the plasma can be attracted in a direction perpendicular to the wafer. Therefore, apparently, the shapes of the side walls after etching are uniform throughout the whole wafer. In addition, since the electric field intensity provided by the bias potential is uniform even at the wafer peripheral edge, kinetic energies of the charged particles in the plasma are uniform, so that the etching rate does not vary. Therefore, according to the present invention, the area being subject to E.E. can be reduced.

In practice, a silicon wafer was etched with the etching apparatus including the conductor ring 132 shown in FIG. 2. The side wall shape and depth of the trench formed after the etching, or etching rate, was verified, and it was proved that an advantageously uniform etching had been accomplished from the center of the wafer throughout the vicinity of the peripheral edge thereof.

Now, a second embodiment of the present invention will be described in detail with reference to the drawings.

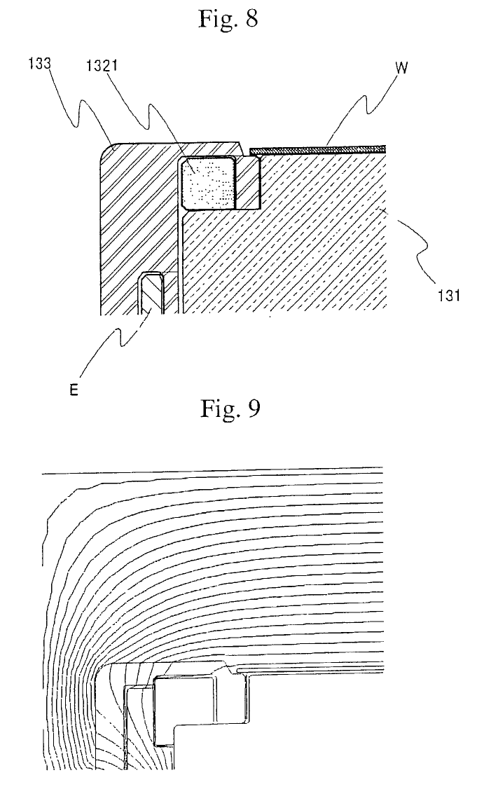

In FIG. 8, the shapes of the conductor ring 132 and cover ring 133 of the lower electrode 130 differ from those in the first embodiment. In FIG. 8, the difference Hw−Hf is 0.6 mm, and the difference Df−Ds is 3.5 mm. FIG. 9 shows a result of analysis of the electric field distribution provided by the bias potential at this time. As can be seen from FIG. 9, equipotential surfaces provided by the bias potential are substantially parallel with the upper surface of the wafer W from the vicinity of the center thereof to the peripheral edge thereof. This result is substantially the same as that shown in FIG. 3 in the case where the conductor ring 132 is used as shown in FIG. 2.

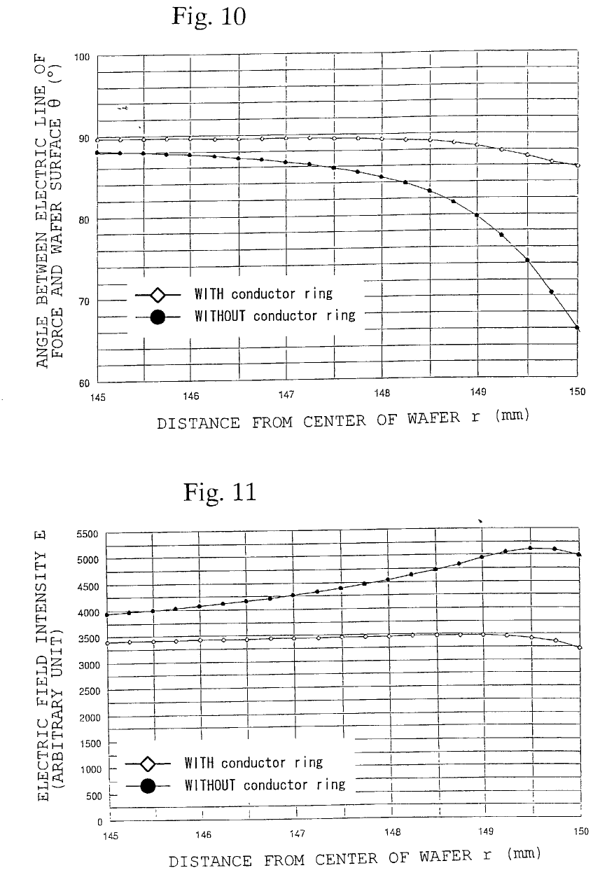

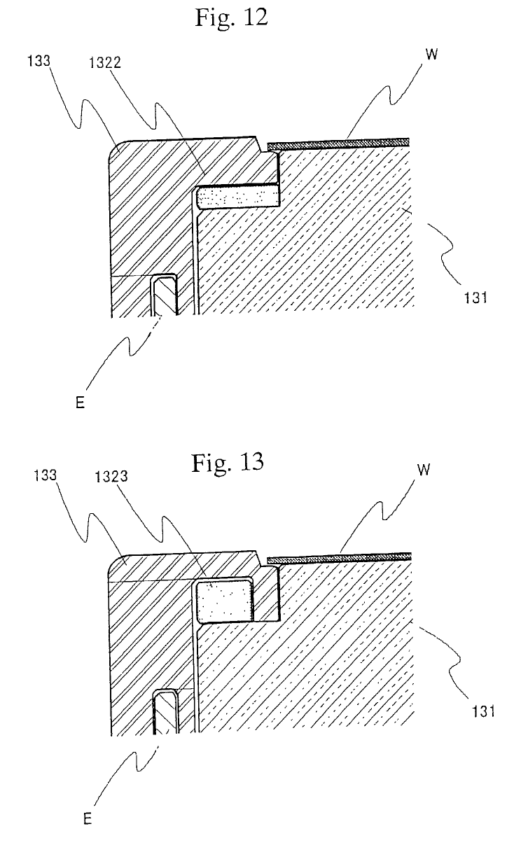

FIG. 10 is a graph showing a result of analysis of the relation between a distance r from the center of the wafer W and an angle θ between an electric line of force at a position 1 mm above the wafer and the wafer surface. If a conductor ring 1321 is used, the angle of the electric line of force is substantially perpendicular to the wafer surface up to the wafer edge. This is apparently different from the case where the conductor ring is not used, in which the angle of the electric line of force becomes considerably smaller at the wafer edge. FIG. 11 is a graph showing the result of analysis of a relation between a distance r from the center of the wafer W and an electric field intensity E at a position 1 mm above the wafer. If the conductor ring 1321 is used, the electric field intensity is substantially uniform throughout even the outermost edge of the wafer. To the contrary, if the conductor ring is not used, the electric field intensity apparently increases at the wafer peripheral edge.

In practice, a silicon wafer was etched using the etching apparatus including the conductor ring 1321 shown in FIG. 8. The side wall shape and depth of the trench formed after the etching, or etching rate, was verified, and it was proved that an advantageously uniform etching had been accomplished from the center of the wafer throughout the vicinity of the peripheral edge thereof.

Now, another embodiment of the present invention will be described with reference to the drawings.

In FIGS. 12 and 13, the shapes of the conductor ring 132 and cover ring 133 of the lower electrode 130 differ from those in the first embodiment. In FIG. 12, the difference Hw−Hf is 6 mm, and the difference Df−Ds is 0.6 mm. In FIG. 13, the difference Hw−Hf is 1.6 mm, and the difference Df−Ds is 8 mm. In these embodiments, a silicon wafer was etched in practice, and the side wall shape and depth of the trench formed after etching, or etching rate, was verified. Thereby, it was proved that an advantageously uniform etching had been accomplished from the center of the wafer throughout the vicinity of the peripheral edge thereof.

Next, allowable values of the differences Hw−Hf and Df−Ds are further studied.

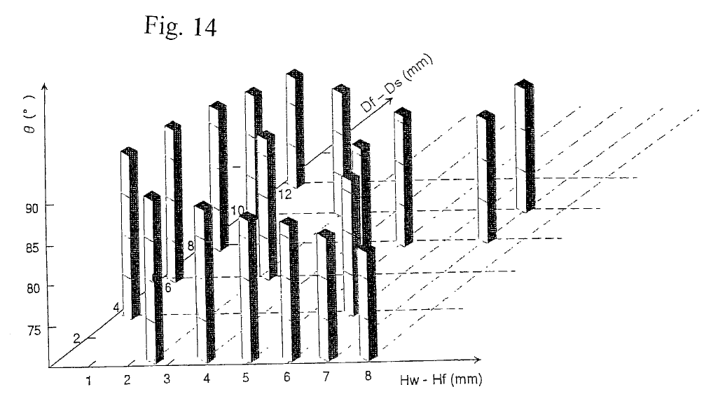

FIG. 14 is a graph showing the relation among the difference Hw−Hf, the difference Df−Ds and the angle θ between the electric line of force and the wafer surface. Further, from measurement results by another detailed experiment conducted separately, it is proved that if the wafer has a diameter of 300 mm, etching is sufficiently accomplished when the distance r from the center of the wafer is 149 mm, and the angle θ at a point 1 mm above the wafer is equal to or more than 85° and equal to or less than 95°. Based on these results, in FIG. 14, the ranges of the differences Hw−Hf and Df−Ds in which the angle θ is equal to or more than 85° and equal to or less than 95° were examined. Then, it was proved that the ranges where Hw−Hf ≦7 and Df−Ds ≦10 are suitable.

As described above, the present invention provides a plasma processing apparatus capable of creating a uniform electric field intensity throughout the wafer up to the peripheral edge thereof and processing the wafer uniformly in the plane thereof, even if the apparatus is of a type in which wafers are delivered one after another by automatic delivery means to be mounted horizontally on sample holder means and held thereto by electrostatic chucking, having a bias potential applied to the sample holder means. Furthermore, in the arrangement according to the present invention, the “wall” located higher than the upper surface of the wafer which has been used in the prior art can be eliminated. Therefore, the disadvantages caused by the contaminant adhered on the “wall” falling on the wafer surface can be prevented.

The present invention is not limited to the application to the plasma etching apparatus illustrated in the first to third embodiments described above.

What is claimed is:

1. A plasma processing apparatus, comprising:
a process chamber for processing a sample;
evacuation means for decompressing said process chamber;
process gas supply means for supplying a process gas to said process chamber;
sample holder means for holding the sample processed in said process chamber;
bias applying means for applying a bias potential to said sample holder means;
electrostatic chucking means for holding said sample to said sample holder means with electrostatic action; and
plasma generator means for generating a plasma in said process chamber,
wherein said sample holder means has a step on an upper surface thereof, said sample is mounted on the uppermost step, a ring member made of a conductive material to which said bias potential can be applied is provided on a surface lower than the surface on which said sample is mounted, the upper surface of said ring member is at the same level as or below the upper surface of said sample, and the upper surface of said ring member is covered with a member made of a dielectric material.

2. The plasma processing apparatus according to claim 1, wherein the difference between the height of the upper surface of said ring member and the height of the upper surface of said sample is equal to or less than 7 mm, and the difference between the inner diameter of said ring member and the outer diameter of the uppermost step of said sample holder means is equal to or less than 10 mm.

3. The plasma processing apparatus according to claim 1, wherein said ring member made of a conductive material is made of the same material as a base material of said sample holder means.

4. The plasma processing apparatus according to claim 1, wherein said member made of a dielectric material is made of ceramic or quartz.

5. The plasma processing apparatus according to claim 1, wherein the surface of said ring member made of a conductive material is covered with a film made of a dielectric material.

6. The plasma processing apparatus according to claim 5, wherein said film made of a dielectric material is a thermal-sprayed film or anodized film.
